(19) United States
(12) Patent Application Publication
(10) Pub. No.: US 2016/0355923 A1
(43) Pub. Date: Dec. 8, 2016

(54) VACUUM EVAPORATION DEVICE AND VACUUM EVAPORATION METHOD

(71) Applicants: BOE TECHNOLOGY GROUP CO., LTD., Beijing (CN); HEFEI XINSHENG OPTOELECTRONICS TECHNOLOGY CO. LTD., Hefei, Anhui (CN)

(72) Inventors: Junying MU, Beijing (CN); Dawei MA, Beijing (CN)

(73) Assignees: BOE TECHNOLOGY GROUP CO., LTD., Beijing (CN); HEFEI XINSHENG OPTOELECTRONICS TECHNOLOGY CO. LTD., Anhui (CN)

(21) Appl. No.: 14/436,360

(22) PCT Filed: Aug. 5, 2014
(86) PCT No.: PCT/CN2014/083682

§ 371 Date: Aug. 17, 2016

(30) Foreign Application Priority Data
Mar. 7, 2014 (CN) 201410081835.4

(51) Int. Cl. C23C 14/04; C23C 14/50; C23C 14/54; C23C 14/24

(52) U.S. Cl. CPC C23C 14/042; C23C 14/24; C23C 14/50; C23C 14/54

(57) ABSTRACT

The present disclosure provides a vacuum evaporation device, including: a substrate driving mechanism for supporting and moving a substrate; a first mask plate driving mechanism for supporting and moving a first mask plate located below the substrate; a second mask plate driving mechanism for supporting and moving a second mask plate located below the first mask plate, the second mask plate driving mechanism cooperating with the first mask plate driving mechanism so as to change an overlapping state of mask plate pattern regions of the first mask plate and the second mask plate; and an evaporation source located below the second mask plate.

### CROSS-REFERENCE TO RELATED APPLICATION

The present application claims a priority of the Chinese patent application No. 201410081835.4 filed on Mar. 7, 2014, which is incorporated herein by reference in its entirety.

### TECHNICAL FIELD

The present disclosure relates to the field of thin film forming technology, in particular to a vacuum evaporation device and a vacuum evaporation method.

### BACKGROUND

Currently, in the photoelectricity and display field, in particular in the field of manufacturing such elements as organic light-emitting diode (OLED) and organic thin film transistor (OTFT), the development of an OLED display technology toward a large-sized substrate is restricted by such factors as unevenness of vacuum evaporation with small organic molecules as well as requirements on the strength and accuracy of a mask plate. In an existing vacuum evaporation device, usually one-step vacuum evaporation is adopted, i.e., respective layers of films are formed on the entire substrate by the one-off evaporation, regardless of a point, line or surface evaporation source.

Referring to FIG. 1, which is a sectional view of the existing vacuum evaporation device, the vacuum evaporation device includes: a substrate driving mechanism (not shown) for moving and supporting a substrate, a surface of which is provided with a pattern region; a mask plate driving mechanism (not shown) for moving and supporting a mask plate 3; an alignment mechanism (not shown) for aligning the substrate with the mask plate 3; and a line evaporation source. The surface of the substrate to be processed by evaporation faces downward, the mask plate 3 is located below the substrate, and the line evaporation source is located below the mask plate 3.

Referring to FIG. 2, which is a top view of the existing substrate, the substrate 1 includes a substrate pattern region 2 formed at the surface of the substrate, and an alignment mark 5 located on the substrate and outside the pattern region.

Referring to FIG. 3, which is a top view of an existing mask plate, the mask plate includes a mask plate pattern region 6, a bezel region 7, and a second alignment mark 8 on the mask plate. The second alignment mark 8 is located at the bezel region 7, and the mask plate pattern region 6 is of a size identical to that of the substrate pattern region.

During the evaporation, the substrate driving mechanism moves the substrate to be above the mask plate 3, and the second alignment mark 8 on the mask plate is aligned with the alignment mark 5 on the substrate by the alignment mechanism. Then, the line evaporation source is turned on, a material is vaporized and moves upward until it reaches the surface of the substrate, and the vaporized material is deposited on the substrate to form a film with a pattern identical to a pattern of an aperture region of the mask plate.

However, the existing vacuum evaporation device mainly has the following drawbacks. For the films with different patterns, the mask plates with different patterns are desired. i.e., the pattern of the mask plate must be identical to the pattern of the film. Hence, for the films with different patterns, it is required to replace different mask plates, which results in an increase in the production cost. In addition, when a film with an irregular pattern is to be processed by evaporation, the pattern region of the mask plate is required to be identical to the pattern region of the substrate. As a result, the accuracy of the mask plate is highly demanded, and it is difficult to manufacture the desired mask plate.

### SUMMARY

An object of the present disclosure is to provide a vacuum evaporation device and a vacuum evaporation method, so as to form films with different patterns without any need to replace a mask plate.

In one aspect, the present disclosure provides a vacuum evaporation device, including:

a substrate driving mechanism for supporting and moving a substrate;

a first mask plate driving mechanism for supporting and moving a first mask plate located below the substrate;

a second mask plate driving mechanism for supporting and moving a second mask plate located below the first mask plate; and

an evaporation source located below the second mask plate.

Further, the first mask plate driving mechanism and the second mask plate driving mechanism move the first mask plate and second mask plate, respectively, so as to change an overlapping state of mask plate pattern regions of the first mask plate and the second mask plate, thereby to form an effective mask plate pattern region corresponding to a pattern region to be processed by evaporation on the substrate.

Further, a surface of the substrate is divided into several sub-regions. The effective mask plate pattern region formed after the first mask plate overlaps the second mask plate is of a size smaller than, or identical to, that of the sub-region.

Further, the vacuum evaporation device further includes:

a shutter located between the substrate and the evaporation source so as to form an vaporized-material passing-through region which is of a size identical to that of the effective mask plate pattern region;

a shutter driving mechanism for moving and supporting the shutter, so as to enable the vaporized-material passing-through region to correspond to a current sub-region of the substrate; and

an evaporation source driving mechanism for moving and supporting the evaporation source, so as to enable the evaporation source to correspond to the current sub-region of the substrate.

Further, the vacuum evaporation device includes an alignment mechanism for aligning the first mask plate and the second mask plate with the current sub-region of the substrate, respectively.

Further, the vacuum evaporation device includes an alignment driving mechanism for moving and supporting the alignment mechanism.

Further, when the effective mask plate pattern region formed after the first mask plate overlaps the second mask plate is of a size identical to that of the sub-region, a first alignment mark is provided outside the sub-region, a second alignment mark is provided at a bezel region of the first mask plate, a third alignment mark is provided at a bezel region of the second mask plate, the first mask plate is aligned with the current sub-region by the alignment mechanism through the first alignment mark and the second alignment mark, and the second mask plate is aligned with the current sub-region by the alignment mechanism through the first alignment mark and the third alignment mark.

Further, when the effective mask plate pattern region formed after the first mask plate overlaps the second mask plate is of a size smaller than that of the sub-region, the first mask plate and the second mask plate are each of a width in a first direction less than the current sub-region of the substrate, so that the effective mask plate pattern region is of a width in the first direction less than the current sub-region of the substrate.

Further, when the effective mask plate pattern region formed after the first mask plate overlaps the second mask plate is of a size smaller than the sub-region, a first alignment mark is provided outside the sub-region, a second alignment mark is provided at a bezel region of the first mask plate, a third alignment mark is provided at a bezel region of the second mask plate, the first mask plate is aligned with a current sub-region by the alignment mechanism before the startup of the evaporation through the first alignment mark and the second alignment mark, and the second mask plate is aligned with the current sub-region by the alignment mechanism before the startup of the evaporation through the first alignment mark and the third alignment mark; and a fourth alignment mark is further provided outside the sub-region, a fifth alignment mark is further provided at the bezel region of the first mask plate, a sixth alignment mark is further provided at the bezel region of the second mask plate, the first mask plate is aligned with the current sub-region by the alignment mechanism during the evaporation through the fourth alignment mark and the fifth alignment mark in a state where a relative position between the first mask plate and the current sub-region is changed continuously in the first direction, and the second mask plate is aligned with the current sub-region by the alignment mechanism during the evaporation through the fourth alignment mark and the sixth alignment mark in a state where a relative position between the second mask plate and the current sub-region is changed continuously in the first direction.

Further, the fourth alignment mark is an elongated structure extending in the first direction and through a corresponding sub-region.

Further, when the effective mask plate pattern region formed after the first mask plate overlaps the second mask plate is of a size smaller than the sub-region, the first mask plate driving mechanism adjusts finely a position of the first mask plate in a second direction in accordance with an alignment result in the state where the relative position between the first mask plate and the current sub-region is changed continuously in the first direction, so that the first mask plate is not offset from the current sub-region; and the second mask plate driving mechanism adjusts finely a position of the second mask plate in the second direction in accordance with an alignment result in the state where the relative position between the second mask plate and the current sub-region is changed continuously in the first direction, so that the second mask plate is not offset from the current sub-region.

Further, the shutter is located below the second mask plate.

Further, the shutter includes four sub-shutters which are driven independently and define the vaporized-material passing-through region.

Further, the evaporation source is a line evaporation source.

In another aspect, the present disclosure provides in one embodiment a vacuum evaporation method, including:

moving, by a substrate driving mechanism, a sub-region on the substrate to be above a first mask plate

aligning, by an alignment mechanism, a first alignment mark on the substrate with a second alignment mark on the first mask plate and a third alignment mark on a second mask plate through adjusting positions of the first mask plate and the second mask plate by a first mask plate driving mechanism and a second mask plate driving mechanism, respectively; and

turning on an evaporation source, so that a material is vaporized and moves upward until it reaches a surface of the substrate and the vaporized material is deposited on the substrate to form a film with a pattern identical to an effective aperture pattern at an effective mask plate pattern region formed after the first mask plate overlaps the second mask plate.

Further, when the effective mask plate pattern region formed after the first mask plate overlaps the second mask plate is of a size identical to that of the sub-region, a first alignment mark is provided outside the sub-region, a second alignment mark is provided at a bezel region of the first mask plate, a third alignment mark is provided at a bezel region of the second mask plate, the first mask plate is aligned with a current sub-region by the alignment mechanism through the first alignment mark and the second alignment mark, and the second mask plate is aligned with the current sub-region by the alignment mechanism through the first alignment mark and the third alignment mark.

Further, when the effective mask plate pattern region formed after the first mask plate overlaps the second mask plate is of a size smaller than that of the sub-region, a first alignment mark is provided outside the sub-region, a second alignment mark is provided at a bezel region of the first mask plate, a third alignment mark is provided at a bezel region of the second mask plate, the first mask plate is aligned with a current sub-region by the alignment mechanism before the startup of the evaporation through the first alignment mark and the second alignment mark, and the second mask plate is aligned with the current sub-region by the alignment mechanism before the startup of the evaporation through the first alignment mark and the third alignment mark; and a fourth alignment mark is further provided outside the sub-region, a fifth alignment mark is further provided at the bezel region of the first mask plate, a sixth alignment mark is further provided at the bezel region of the second mask plate, the first mask plate is aligned with the current sub-region by the alignment mechanism during the evaporation through the fourth alignment mark and the fifth alignment mark in a state where a relative position between the first mask plate and the current sub-region is changed continuously in the first direction, and the second mask plate is aligned with the current sub-region by the alignment mechanism during the evaporation through the fourth alignment mark and the sixth alignment mark in a state where a relative position between the second mask plate and the current sub-region is changed continuously in the first direction.

Further, the fourth alignment mark is an elongated structure extending in the first direction and through a corresponding sub-region

Further, the first mask plate driving mechanism adjusts finely the first mask plate in a second direction in accordance with an alignment result in the state where the relative position between the first mask plate and the current sub-region is changed continuously in the first direction, so that the first mask plate is not offset from the current sub-region. The second mask plate driving mechanism adjusts finely the second mask plate in the second direction in accordance with an alignment result in the state where the relative position between the second mask plate and the current sub-region is changed continuously in the first direction, so that the second mask plate is not offset from the current sub-region.

According to the vacuum evaporation device in the embodiments of the present disclosure, at least two mask plates are provided, and the overlapping state of the mask plate pattern regions of the at least two mask plates may be changed in accordance with a pattern feature of the pattern region to be processed by evaporation at the surface of the substrate, so as to enable the effective mask plate pattern region to match the pattern region to be processed by evaporation at the surface of the substrate, thereby to pattern the films and reduce the production cost of the mask plates.

Further, according to the vacuum evaporation device in the embodiments of the present disclosure, the surface of the substrate is divided into several (e.g., 1 to 10) sub-regions, and the first mask plate and the second mask plate smaller than one sub-region may be used to perform the evaporation on each sub-region in a stepwise manner. An overlapping degree of the mask plate pattern regions of the first mask plate and the second mask plate may be changed continuously during the scanning and evaporation procedure, so as to be adapted to evaporate the films with different patterns at the sub-regions. The vacuum evaporation device may be used for the vacuum evaporation of a large-size substrate and a large-sized display module. Also, according to the embodiments of the present disclosure, it is able to reduce a length of the line evaporation source and improve the evenness of the vacuum evaporation. In addition, the evaporation may be performed using a mask plate having an area several times smaller than the substrate, so as to reduce the difficulty in manufacturing the mask plate.

### BRIEF DESCRIPTION OF THE DRAWINGS

FIG. 1 is a sectional view of an existing vacuum evaporation device;

FIG. 2 is a top view of an existing substrate;

FIG. 3 is a top view of an existing mask plate;

FIG. 4 is a sectional view of a vacuum evaporation device in a second direction according to the first embodiment of the present disclosure;

FIG. 5 is a top view of a substrate according to the first embodiment of the present disclosure;

FIG. 6 is a top view of a first mask plate according to the first embodiment of the present disclosure:

FIG. 7 is a top view of a second mask plate according to the first embodiment of the present disclosure;

FIG. 8 is a schematic view showing a pattern of a film according to the first embodiment of the present disclosure;

FIG. 9 is a schematic view showing a first overlapping state of the first mask plate and the second mask plate;

FIG. 10 is a schematic view showing a second overlapping state of the first mask plate and the second mask plate;

FIG. 11 is a sectional view of the vacuum evaporation device in the second direction according to the second embodiment of the present disclosure;

FIG. 12 is a sectional view of the vacuum evaporation device in a first direction according to the second embodiment of the present disclosure;

FIG. 13 is a schematic view showing a shutter;

FIG. 14 is a top view of the substrate according to the second embodiment of the present disclosure;

FIG. 15 is a sectional view of the vacuum evaporation device in the first direction according to the third embodiment of the present disclosure;

FIG. 16 is a top view of the substrate according to the third embodiment of the present disclosure;

FIG. 17 is a schematic view showing the first mask plate according to the third embodiment of the present disclosure;

FIG. 18 is a schematic view showing the second mask plate according to the third embodiment of the present disclosure;

FIG. 19 is a schematic view showing a pattern of a evaporation sub-region for a block-like pixel; and

FIG. 20 is a schematic view showing a third overlapping state of the first mask plate and the second mask plate.

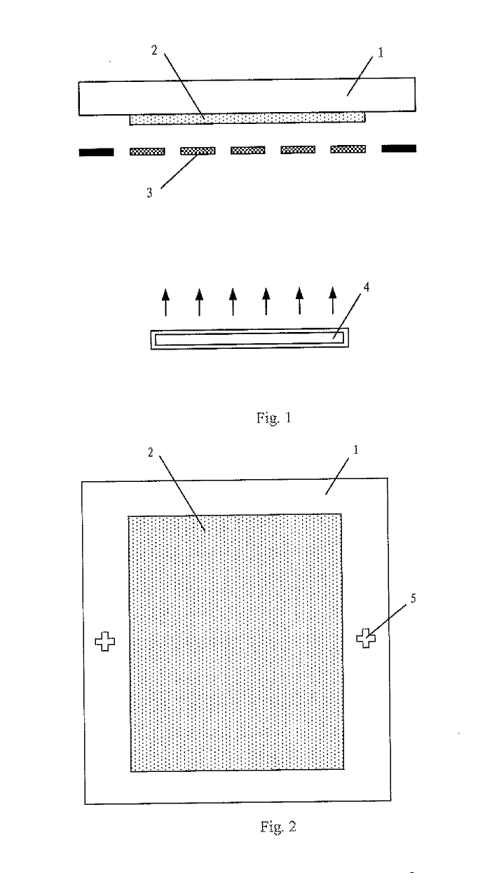

### DETAILED DESCRIPTION

The principles and features of the present disclosure will be described hereinafter in conjunction with the drawings and embodiments. It should be appreciated that, the following embodiments are for illustrative purposes only, but shall not be used to limit the scope of the present disclosure.

In the related art, it is unable to effectively pattern a film by a vacuum evaporation device. In order to solve this problem, the present disclosure provides in the following embodiments a vacuum evaporation device so as to pattern different films.

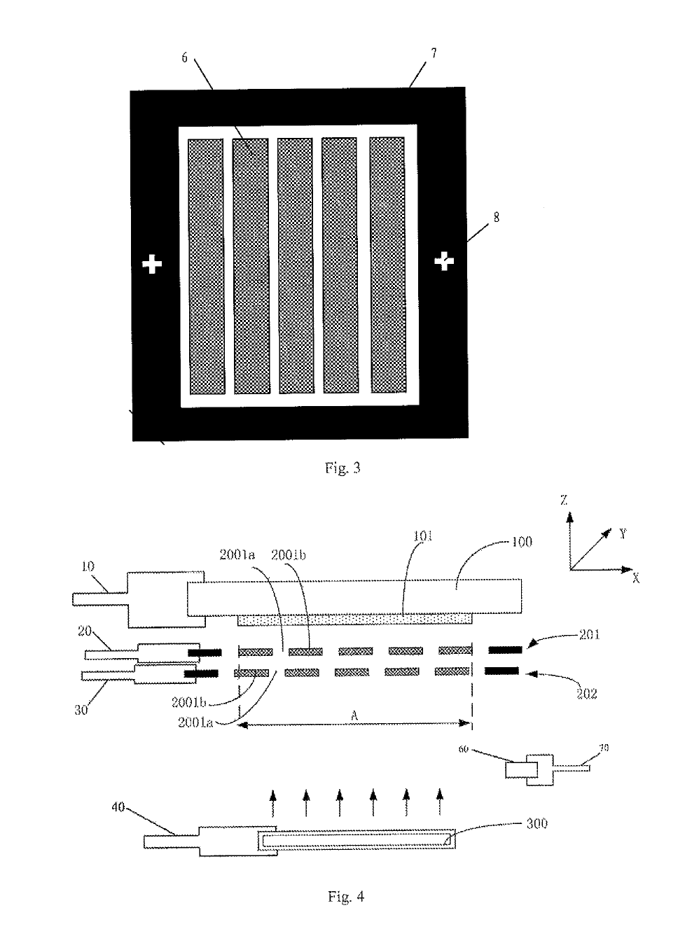

Referring to FIGS. 4-18, the vacuum evaporation device of the present disclosure includes:

a substrate driving mechanism 10 for moving and supporting a substrate 100, a surface of which is provided with a pattern region 101 to be processed by evaporation;

a first mask plate driving mechanism 20 for moving and supporting a first mask plate 201 which is located below the substrate 100;

a second mask plate driving mechanism 30 for moving and supporting a second mask plate 202 which is located below the first mask plate 201; and

an evaporation source 300 which is located below the second mask plate 202.

The first mask plate driving mechanism and the second mask plate driving mechanism move the first mask plate 201 and the second mask plate 202, respectively, so as to change an overlapping state of mask plate pattern regions of the first mask plate 201 and the second mask plate 202, thereby to form an effective mask plate pattern region A corresponding to the pattern region 101 to be processed by evaporation on the substrate 100.

The first mask plate 201 and the second mask plate 202 are each provided with the pattern region and a bezel region, and an aperture portion 2001a and a shielding portion 2001b are formed at the pattern region. When the first mask plate 201 and the second mask plate 202 are located at different relative positions, i.e., when they are in different overlapping states, the aperture portion 2001a of the first mask plate 201 overlaps the aperture portion 2001a of the second mask plate 202 to a different extent, so as to form the effective mask plate pattern region A through which an vaporized material passes. At least two mask plates are moved in accordance with features of the pattern region 101 to be processed by evaporation at the surface of the substrate 100, so as to change the overlapping state of the mask plate pattern regions 2001 of the at least two mask plates, thereby to form the effective mask plate pattern region A that matches a pattern of a film at the pattern region 101 to be processed by evaporation at the surface of the substrate 100. As a result, it is able to pattern the film.

It should be appreciated that, alternatively, there are two mask plates for the vacuum evaporation device in the embodiments of the present disclosure, but the number of the mask plates are not particularly defined herein. For example, there may be three, four or more mask plates. By taking three mask plates as an example, the vacuum evaporation device may further include a third mask plate driving mechanism, which cooperates with the first and second mask plate driving mechanisms so as to change the relative positions of the first, second and third mask plates, respectively, thereby to change the overlapping state of the pattern regions 2001 of the first, second and third mask plates.

The following embodiments are provided for ease of understanding.

### First Embodiment

As shown in FIG. 4, which is a sectional view of the vacuum evaporation device in a second direction X according to the first embodiment of the present disclosure, the vacuum evaporation device includes:

the substrate driving mechanism 10 for moving and supporting the substrate 100, a surface of which is provided with the pattern region 101 to be processed by evaporation;

the first mask plate driving mechanism 20 for moving and supporting the first mask plate 201;

the second mask plate driving mechanism 30 for moving and supporting the second mask plate 202;

an alignment mechanism for aligning the first mask plate 201 and the second mask plate 202 with the substrate 100, respectively; and

the evaporation source 300 which is located below the second mask plate 202.

The effective mask plate pattern region A formed after the first mask plate 201 overlaps the second mask plate 202 is of a size identical to that of the entire pattern region 101 to be processed by evaporation.

Alternatively, the vacuum evaporation device further includes an evaporation source driving mechanism 40 for moving and supporting the evaporation source 300.

In this embodiment, the surface of the substrate 100 to be processed faces downward, the first mask plate 201 is located below the substrate 100, the second mask plate 202 is located below the first mask plate 201, and the line evaporation source 300 is located below the second mask plate 202.

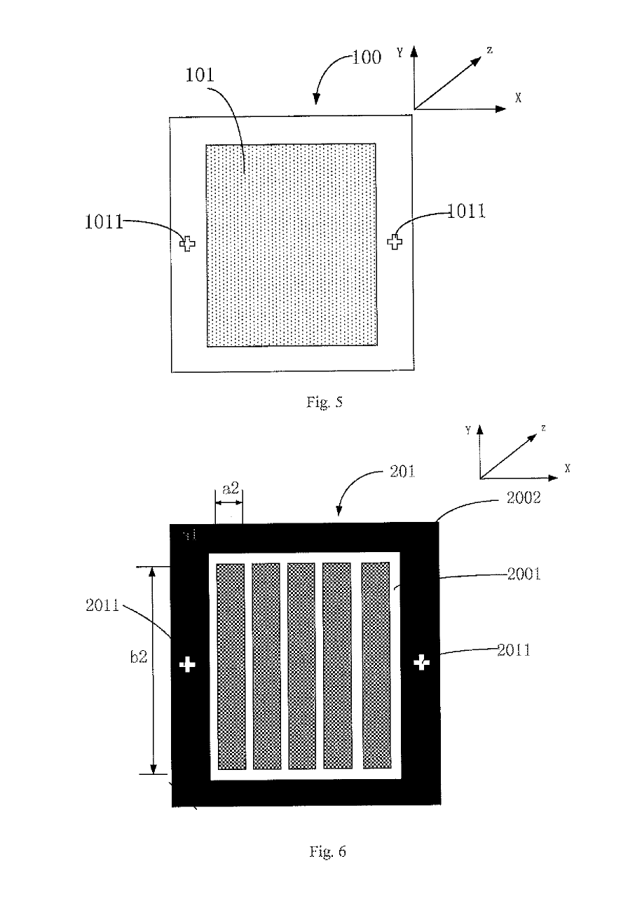

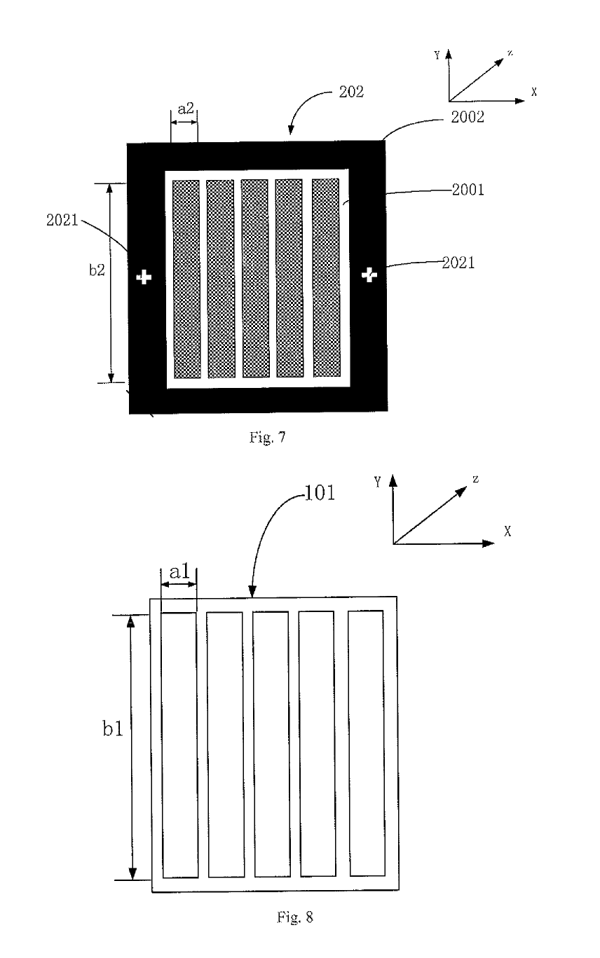

As shown in FIG. 5, which is a top view of the substrate according to the first embodiment of the present disclosure, the substrate 100 includes the pattern region 101 to be processed by evaporation at the surface of the substrate 100, and a first alignment mark 1011 provided outside the pattern region 101. In this embodiment, two first alignment marks 1011 are provided outside the pattern region 101 in a bilaterally symmetrical manner. FIG. 6 is a top view of the first mask plate according to the first embodiment of the present disclosure, and FIG. 7 is a top view of the second mask plate according to the first embodiment of the present disclosure. As shown in FIG. 6, the first mask plate 201 includes the mask plate pattern region 2001, a bezel region 2002, and second alignment marks 2011 provided at the bezel region. As shown in FIG. 7, the second mask plate 202 includes the mask plate pattern region 2001, a bezel region 2002, and third alignment marks 2021 provided at the bezel region 2002. There are two second alignment marks 2011 on the first mask plate 201 and two third alignment marks 2021 on the second mask plate 202.

In this embodiment, alternatively, the first mask plate 201 is of a structure identical to that of the second mask plate 202, and the mask plate pattern regions 2001 of the first mask plate 201 and the second mask plate 202 are each of a size identical to that of the entire pattern region 101 to be processed by evaporation. It should be appreciated that, in the actual application, the first mask plate 201 and the second mask plate 202 may also be of different structures, and the mask plate pattern regions of the first mask plate 201 and the second mask plate 202 may each be of a size different from that of the entire pattern region 101 to be processed by evaporation, as long as the effective mask plate pattern region A formed after the pattern regions 2001 of the first mask plate 201 and the second mask plate 202 overlap each other is of a size identical to that of the entire pattern region 101 to be processed by evaporation on the substrate 100.

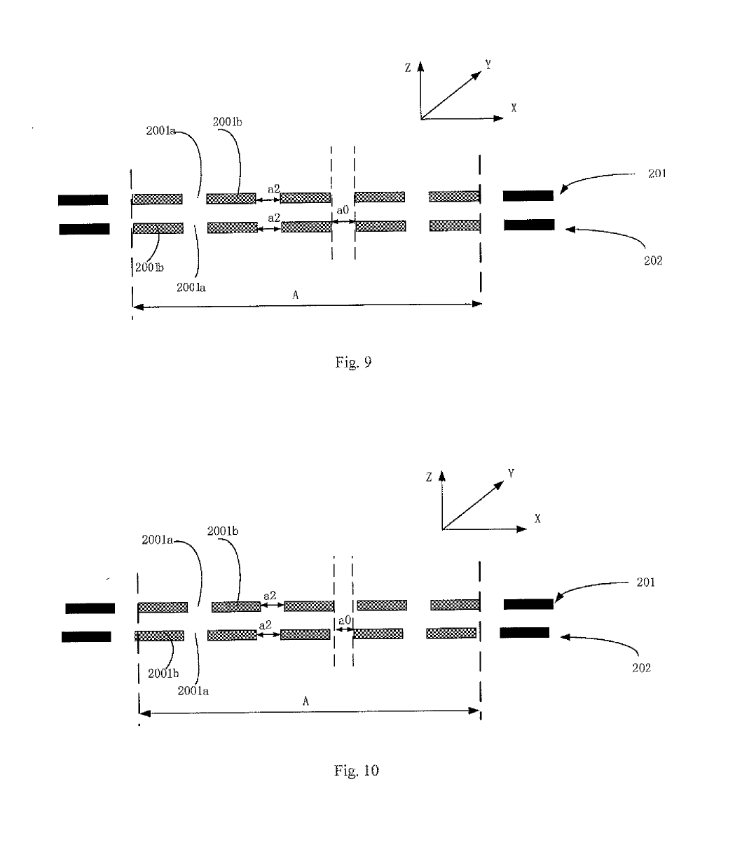

FIG. 8 is a schematic view showing the pattern of the film at the pattern region to be processed by evaporation on the substrate according to the first embodiment of the present disclosure, and FIGS. 9 and 10 are schematic views showing the relative position relationship between the first mask plate and the second mask plate.

Before the startup of the evaporation, the first mask plate 201 is aligned with the pattern region 101 to be processed by evaporation on the substrate 100 by the alignment mechanism through the first alignment marks 1011 on the substrate 100 and the second alignment marks 2011 on the first mask plate 201, and the second mask plate 202 is aligned with the pattern region 101 to be processed by evaporation on the substrate 100 by the alignment mechanism through the first alignment marks 1011 on the substrate 100 and the third alignment marks 2021 on the second mask plate 202. To be specific, the substrate 100 and/or the first/second mask plates 201, 202 are moved, so as to enable the corresponding first alignment marks 1011 on the substrate 100 to visually overlap the corresponding second and third alignment marks on the first and second mask plates, respectively, thereby to complete the alignment.

When the pattern of the film at the pattern region 101 to be processed by evaporation on the substrate 100 is of a size identical to that of the aperture portion 2001a of the mask plate pattern region 2001 of the first mask plate 201, as shown in FIG. 9, after the completion of the alignment, the aperture portions 2001a of the mask plate pattern regions 2001 of the first mask plate 201 and the second mask plate 202 overlap each other exactly, the effective mask plate pattern region A formed after the first mask plate 201 overlaps the second mask plate 202 is of a size identical to that of the pattern region 101 to be processed by evaporation on the substrate 100, and an effective aperture portion of the effective mask plate pattern region A is of a size identical to that of the pattern of the film at the pattern region 101 to be processed by evaporation.

When a width a1 of the pattern of the film at the pattern region 101 to be processed by evaporation on the substrate 100 in the second direction X is smaller than a width a2 of the aperture portion 2001a of the mask plate pattern region 2001 of the first mask plate 201 in the second direction X and a width b1 of the pattern of the film at the pattern region 101 to be processed by evaporation on the substrate 100 in the first direction Y is identical to a width b2 of the aperture portion 2001a of the mask plate pattern region 2011 of the first mask plate 201 in the first direction Y, after the completion of the alignment, the aperture portions 2001a of the mask plate pattern regions 2001 of the first mask plate 201 and the second mask plate 202 partially overlap each other in the second direction X (i.e., as shown in FIG. 10, the aperture portion 2001a of the first mask plate 201 is partially shielded by the shielding portion 2001b of the second mask plate 202), a width a0 of the effective aperture portion at the effective mask plate pattern region A formed after the first mask plate 201 overlaps the second mask plate 202 in the second direction X is identical to the width a1 of the pattern of the film at the pattern region 101 to be processed by evaporation in the second direction X, and the effective mask plate pattern region A is of a size identical to that of the pattern region 101 to be processed by evaporation.

Identically, when the width b1 of the pattern of the film at the pattern region 101 to be processed by evaporation on the substrate 100 in the first direction Y is identical to or different from the width b2 of the aperture portion 2001a of the mask plate pattern region 2001 of the first mask plate 201 in the first direction Y, after the completion of the alignment, the effective aperture portion at the effective mask plate pattern region A formed after the first mask plate 201 overlaps the second mask plate 202 is of a size identical to that of the pattern of the film at the pattern region 101 to be processed by evaporation, and the effective mask plate pattern region A is of a size identical to that of the pattern region 101 to be processed by evaporation.

During the evaporation, the pattern region 101 to be processed by evaporation on the substrate 100 is moved by the substrate driving mechanism to be above the first mask plate 201. The corresponding first alignment marks 1011 on the substrate 100 are aligned by the alignment mechanism with the second alignment marks 2011 and the third alignment marks 2021 on the first mask plate 201 and the second mask plate 202, by adjusting the positions of the first mask plate 201 and the second mask plate 202 with the first mask plate driving mechanism and the second mask plate driving mechanism, respectively. Then, the evaporation source 300 is turned on, and the material is vaporized and moves upward until it reaches the surface of the substrate 100. The vaporized material is then deposited to form a film with a pattern identical to the pattern of the effective aperture portion at the effective mask plate pattern region A formed after the first mask plate 201 overlaps the second mask plate 202.

In this embodiment, the effective mask plate pattern region A formed after the first mask plate 201 overlaps the second mask plate 202 may be of a size identical to that of the entire pattern region 101 to be processed by evaporation. As a result, it is able to change the overlapping state of the first mask plate 201 and the second mask plate 202 in accordance with the pattern features of the respectively layers of films, thereby to form the films on the entire substrate 100 by the one-off evaporation (i.e., by one-step vacuum evaporation).

### Second Embodiment

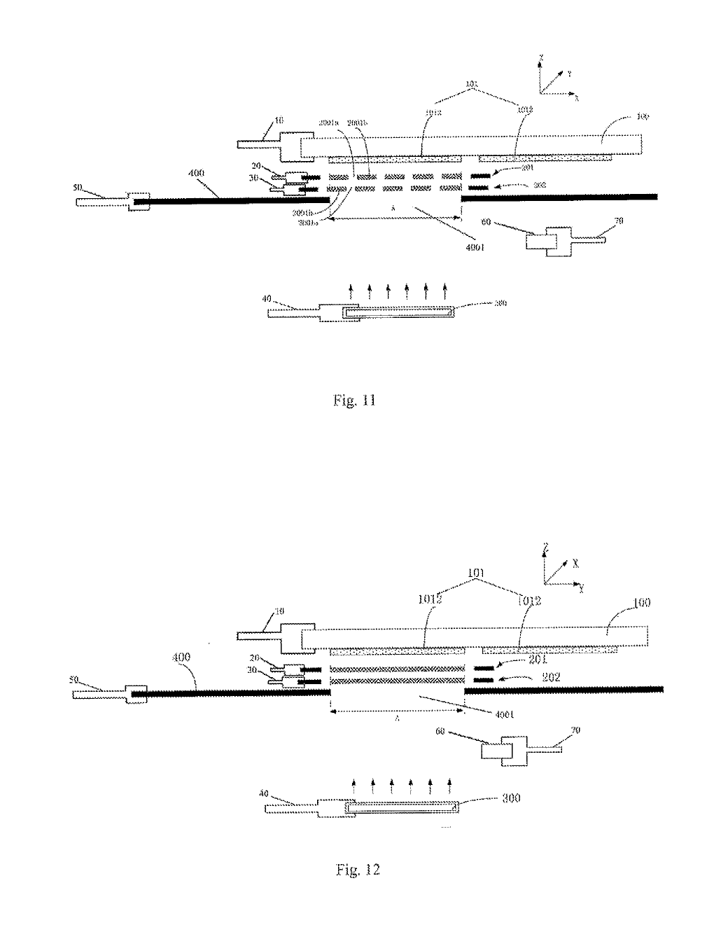

Referring to FIG. 11, which is a sectional view of the vacuum evaporation device in the second direction X according to the second embodiment of the present disclosure, and FIG. 12, which is a sectional view of the vacuum evaporation device in the first direction Y according to the second embodiment of the present disclosure, the vacuum evaporation device includes:

the line evaporation source 300;

the substrate driving mechanism 10 for moving and supporting the substrate 100, a surface of which is provided with the pattern region 101 to be processed by evaporation, the pattern region 101 being divided into several sub-regions 1012 with an identical size;

the first mask plate driving mechanism 20 for moving and supporting the first mask plate 201;

the second mask plate driving mechanism 30 for moving and supporting the second mask plate 202, the effective mask plate pattern region A formed after the first mask plate 201 overlaps the second mask plate 202 being of a size identical to that of the sub-region 1012;

an alignment mechanism 60 for aligning the first mask plate 201 and the second mask plate 202 with the sub-region 1012 to be processed by evaporation, respectively;

a shutter 400 located between the substrate 100 and the line evaporation source 300, so as to form a vaporized-material passing-through region 4001 with a size identical to that of the effective mask plate pattern region A, and a vaporized-material shielding region for shielding the sub-regions 1012 other than a current sub-region 1012; and

a shutter driving mechanism 50 for moving and supporting the shutter 400, the shutter 400 being moved by the shutter driving mechanism so as to form the vaporized-material passing-through region 4001 corresponding to the current sub-region 1012 (i.e., to shield the sub-regions of the substrate 100 that are not to be processed by evaporation but merely expose the current sub-region 1012 corresponding to the vaporized-material passing-through region 4001).

The surface of the substrate 100 to be processed by evaporation faces downward, the first mask plate 201 and the second mask plate 202 are located below the substrate 100, and the shutters 400 are located below the substrate 100 and between the substrate 100 and the line evaporation source 300.

It should be appreciated that, in this embodiment, the shutter 400 may be provided between the first mask plate 201 and the substrate 100, or below the second mask plate 202, or between the first mask plate 201 and the second mask plate 202. Of course, the shutter 400 may also be provided at any other positions between the substrate 100 and the line evaporation source 300, as long as the vaporized-material passing-through region 4001 corresponds to the current sub-region 1012 and the vaporized-material shielding region can shield the sub-regions of the substrate 100 that are not to be processed by evaporation but merely expose the current sub-region 1012 corresponding to the vaporized-material passing-through region 4001. Alternatively, the shutter 400 is located below the second mask plate 202, and the line evaporation source 300 is located below the shutter 400. In this way, it is able to ensure relatively short distances between the first/second mask plates 201, 202 and the substrate 100, respectively, thereby to ensure a relatively short distance for the vaporized material when it passes through the mask plate pattern region and reaches the surface of the substrate. As a result, it is able to ensure the accuracy of the film to be formed by evaporation.

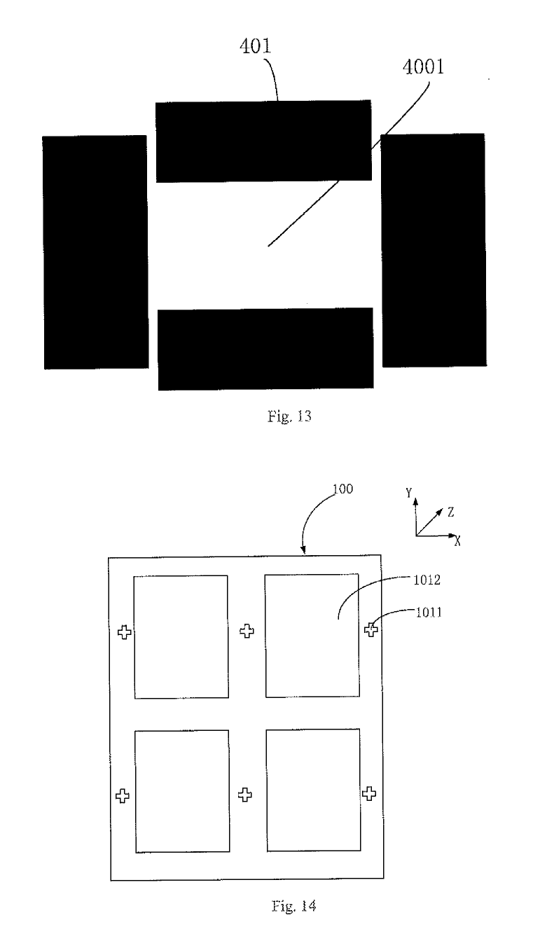

Referring to FIG. 13, which is a top view of the shutter 400 according to an embodiment of the present disclosure, the shutter 400 includes four sub-shutters 401 that are driven independently and define the vaporized-material passing-through region 4001. It should be appreciated that, the number of the sub-shutters 401 may be set in accordance with the practical need, e.g., three or five sub-shutters 401 may be provided.

Referring to FIG. 14, which is a top view of the substrate 100 according to an embodiment of the present disclosure, the substrate 100 includes the pattern region 101 to be processed by evaporation at the surface of the substrate 100, and the first alignment marks 1011 on the substrate 100. The pattern region 101 to be processed by evaporation is divided into several sub-regions 1012 with an identical size. In this embodiment, the pattern region 101 to be processed by evaporation is divided into four sub-regions 1012, and two first alignment marks 1011 are provided outside each sub-region 1012 in a bilaterally symmetrical manner.

The structures of the first mask plate and the second mask plate in this embodiment are identical to those mentioned in the first embodiment. As shown in FIG. 6, the first mask plate 201 includes the mask plate pattern region 2001, the bezel region 2002, and the second alignment marks 2011 at the bezel region 2002. As shown in FIG. 7, the second mask plate 202 includes the mask plate pattern region 2001, the bezel region 2002, and the third alignment marks 2021 at the bezel region 2002. There are two second alignment marks 2011 on the first mask plate 201 and two third alignment marks 2021 on the second mask plate 202.

In this embodiment, alternatively, the first mask plate 201 and the second mask plate 202 are of an identical structure, and the mask plate pattern regions 2001 of the first mask plate 201 and the second mask plate 202 are each of a size identical to the sub-region 1012. Of course, it should be appreciated that, in the actual application, the first mask plate 201 and the second mask plate 202 may also be of different structures, and their mask plate pattern regions 2001 may each be of a size different from the sub-region 1012, as long as the effective mask plate pattern region A formed after the mask plate pattern regions 2001 of the first mask plate 201 and the second mask plate 202 overlap each other is of a size identical to that of the sub-region 1012.

In this embodiment, the pattern of the film at the sub-region 1012 on the substrate 100 is identical to that at the entire pattern region to be processed by evaporation in the first embodiment, and the relative position relationship between the first mask plate 201 and the second mask plate 202 is also identical to that mentioned in the first embodiment.

Before the startup of the evaporation, the first mask plate 201 is aligned with the current sub-region 1012 by the alignment mechanism through the first alignment marks 1011 on the substrate 100 and the second alignment marks 2011 on the first mask plate 201, and the second mask plate 202 is aligned with the current sub-region 1012 by the alignment mechanism through the first alignment marks 1011 on the substrate 100 and the third alignment marks 2021 on the second mask plate 202. To be specific, the substrate 100 and/or the first/second mask plates 201, 202 are moved, so as to enable the corresponding first alignment marks 1011 on the substrate 100 to visually overlap the corresponding second and third alignment marks 2011, 2021 on the first and second mask plates 201, 202, respectively, thereby to complete the alignment.

When the pattern of the film at the sub-region 1012 on the substrate 100 is of a size identical to that of the aperture portion 2001a of the mask plate pattern region 2001 of the first mask plate 201, as shown in FIG. 9, after the completion of the alignment, the aperture portions 2001a of the mask plate pattern regions 2001 of the first mask plate 201 and the second mask plate 202 overlap each other exactly, the effective mask plate pattern region A formed after the first mask plate 201 overlaps the second mask plate 202 is of a size identical to that of the pattern of the film at the sub-region 1012, and an effective aperture portion of the effective mask plate pattern region A is of a size identical to that of the pattern of the film at the sub-region 1012.

When a width a1 of the pattern of the film at the sub-region 1012 to be processed by evaporation on the substrate 100 in the second direction X is smaller than a width a2 of the aperture portion 2001a of the mask plate pattern region 2011 of the first mask plate 201 in the second direction X and a width b1 of the pattern of the film at sub-region 1012 to be processed by evaporation on the substrate 100 in the first direction Y is identical to a width b2 of the aperture portion 2001a of the mask plate pattern region 2011 of the first mask plate 201 in the first direction Y, after the completion of the alignment, the aperture portions 2001a of the mask plate pattern regions 2001 of the first mask plate 201 and the second mask plate 202 partially overlap each other in the second direction X (i.e., as shown in FIG. 10, the aperture portion 2001a of the first mask plate 201 is partially shielded by the shielding portion 2001b of the second mask plate 202), a width a0 of the effective aperture portion at the effective mask plate pattern region A formed after the first mask plate 201 overlaps the second mask plate 202 in the second direction X is identical to the width a1 of the pattern of the film at sub-region 1012 to be processed by evaporation in the second direction X, and the effective mask plate pattern region A is of a size identical to that of the film at the entire sub-region 1012 to be processed by evaporation.

Identically, when the width b1 of the pattern of the film at the sub-region 1012 to be processed by evaporation on the substrate 100 in the first direction Y is identical to or different from the width b2 of the aperture portion 2001a of the mask plate pattern region 2001 of the first mask plate 201 in the first direction Y, after the completion of the alignment, the effective aperture portion at the effective mask plate pattern region A formed after the first mask plate 201 overlaps the second mask plate 202 is of a size identical to that of the pattern of the film at the sub-region 1012 to be processed by evaporation, and the effective mask plate pattern region A is of a size identical to that of the sub-region 1012 to be processed by evaporation.

During the evaporation, a first sub-region 1012 to be processed by evaporation on the substrate 100 is moved by the substrate driving mechanism to be above the mask plate. The corresponding first alignment marks 1011 on the substrate 100 are aligned by the alignment mechanism with the second alignment marks and the third alignment marks on the first mask plate and the second mask plate, by adjusting the positions of the mask plates with the mask plate driving mechanisms, respectively. The four sub-shutters 401 are moved in a horizontal direction by the shutter driving mechanism to specified positions, so as to shield the regions other than the sub-region to be processed by evaporation on the substrate 100. Then, the evaporation source 300 is turned on, and the material is vaporized and moves upward until it reaches the surface of the substrate 100. The vaporized material is then deposited to form a film with a pattern identical to the pattern of the effective mask plate pattern region A formed after the first mask plate overlaps the second mask plate. After the first sub-region 1012 is processed, the above operations are repeated so as to process the other sub-regions 1012, e.g., a second sub-region 1012, until the entire substrate 100 is processed by the vacuum evaporation.

It should be appreciated that, in this embodiment, the sub-regions 1012 are of an identical area. Of course, in the other embodiments, the sub-regions 1012 may also be of different areas, and at this time, it is required to move the shutter 400 or adjust the relative position relationship among the sub-shutters 401, so as to shield a part of the mask plate pattern region.

In addition, it should be further appreciated that, in this embodiment, the patterns of the films at the sub-regions 1012 may be different from each other, and at this time, the positions of the first alignment marks 1011 outside the sub-regions 1012, the second alignment marks 2011 on the first mask plate 201 and the third alignment marks 2012 on the second mask plate 202 may be changed so as to pattern the films at different sub-regions 1012.

In this embodiment, the vacuum evaporation device is a distributed vacuum evaporation device. According to the features of the pattern regions to be processed by evaporation at the surface of the substrate 100, the surface of the substrate 100 is divided into several (e.g., 1 to 10) sub-regions 1012, and the evaporation is performed on each sub-regions 1012 using the mask plates each having an area several times smaller than the substrate 100 in a stepwise manner. When the sub-region 1012 with a relatively small area is processed by evaporation, it is able to reduce a length of the line evaporation source 300 and improve the evenness of the vacuum evaporation. When the mask plate having an area several times smaller than the substrate 100 is used, it is able to reduce the difficulty in manufacturing the mask plate, thereby to perform the vacuum evaporation on a large-sized substrate 100 and a large-sized display module.

### Third Embodiment

The sectional structure of the vacuum evaporation device in the second direction X in this embodiment is identical to that mentioned in the second embodiment. FIG. 15 is a sectional view showing the vacuum evaporation device in the first direction Y according to this embodiment of the present disclosure.

Referring to FIGS. 11 and 15, the vacuum evaporation device in this embodiment includes:

the line evaporation source 300;

the substrate driving mechanism 10 for moving and supporting the substrate 100, a surface of which is provided with the pattern region 101 to be processed by evaporation, the pattern region 101 being divided into several sub-regions 1012 with an identical size;

the first mask plate driving mechanism 20 for moving and supporting the first mask plate 201;

the second mask plate driving mechanism 30 for moving and supporting the second mask plate 202, the effective mask plate pattern region A formed after the first mask plate 201 overlaps the second mask plate 202 being of a size smaller than that of the sub-region 1012;

the alignment mechanism 60 for aligning the first mask plate 201 and the second mask plate 202 with the sub-region 1012 to be processed by evaporation, respectively;

an alignment driving mechanism 70 for moving and supporting the alignment mechanism;

a the shutter 400 for defining the vaporized-material passing-through region 4001 with a size identical to the effective mask plate pattern region A; and

the shutter driving mechanism 50 for moving and supporting the shutter 400, the shutter 400 being moved by the shutter driving mechanism so as to form the vaporized-material passing-through region 4001 corresponding to a part of the sub-region 1012 to be processed by evaporation (i.e., to shield the sub-regions of the substrate 100 that are not to be processed by evaporation but merely expose the part of the sub-region 1012 corresponding to the vaporized-material passing-through region 4001).

The surface of the substrate 100 to be processed by evaporation faces downward, the first mask plate 201 and the second mask plate 202 are located below the substrate 100, and the shutter 400 is located below the substrate 100 and between the substrate 100 and the line evaporation source 300.

It should be appreciated that, in this embodiment, the shutter 400 may be provided between the first mask plate 201 and the substrate 100, or below the second mask plate 202, or between the first mask plate 201 and the second mask plate 202. Of course, the shutter 400 may also be provided at any other positions between the substrate 100 and the line evaporation source 300, as long as the vaporized-material passing-through region 4001 corresponds to a part of the current sub-region 1012 and the vaporized-material shielding region can shield the sub-regions of the substrate 100 that are not to be processed by evaporation but merely expose the part of the current sub-region 1012 corresponding to the vaporized-material passing-through region 4001. Alternatively, the shutter 400 is located below the second mask plate 202, and the line evaporation source 300 is located below the shutter 400. In this way, it is able to ensure relatively short distances between the first/second mask plates 201, 202 and the substrate 100, respectively, thereby to ensure a relatively short distance for the vaporized material when it passes through the mask plate pattern region and reaches the surface of the substrate. As a result, it is able to ensure the accuracy of film to be formed by evaporation.

In this embodiment, the structure of the shutter 400 is identical to that mentioned in the second embodiment. Referring to FIG. 13, the shutter 400 in this embodiment includes four sub-shutters 401 that are driven independently and define the vaporized-material passing-through region 4001. It should be appreciated that, the number of the sub-shutters 401 may be set in accordance with the practical need, e.g., three or five sub-shutters 401 may be provided.

It should be appreciated that, the substrate driving mechanism 10, the first mask plate driving mechanism 20, the second mask plate driving mechanism 30, the evaporation source driving mechanism 40, the shutter driving mechanism 50 and the alignment driving mechanism 70 may be any devices capable of moving and supporting the substrate, the first mask plate, the second mask plate, the evaporation source, the shutter and the alignment mechanism, respectively, e.g., a mechanism arm, or a fixture with a rolling member such as sprocket. These mechanisms provided in the drawings are for illustrative purposes only, but the embodiments of the present disclosure are not limited thereto.

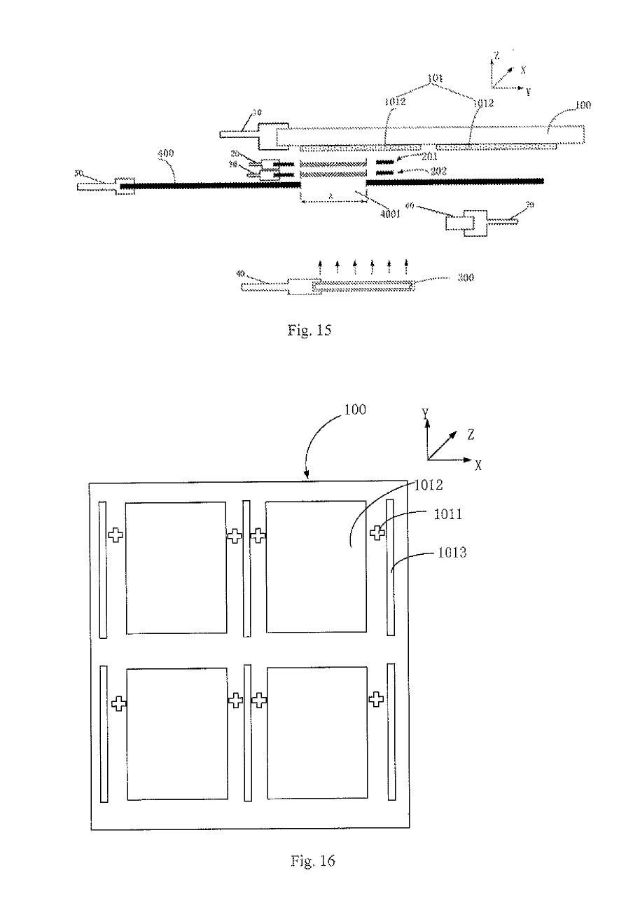

As shown in FIG. 16, which is a top view of the substrate according to this embodiment of the present disclosure, the substrate 100 includes the pattern region 101 to be processed by evaporation at the surface of the substrate 100, and the first alignment marks 1011 on the substrate 100. The pattern region 101 to be processed by evaporation is divided into several sub-regions 1012 with an identical size. In this embodiment, the pattern region 101 to be processed by evaporation is divided into four sub-regions 1012, and two first alignment marks 1011 and two fourth alignment marks 1013 are provided outside each sub-region 1012. Alternatively, the fourth alignment mark 1013 is an elongated structure extending in the first direction Y and through the entire sub-region 1012.

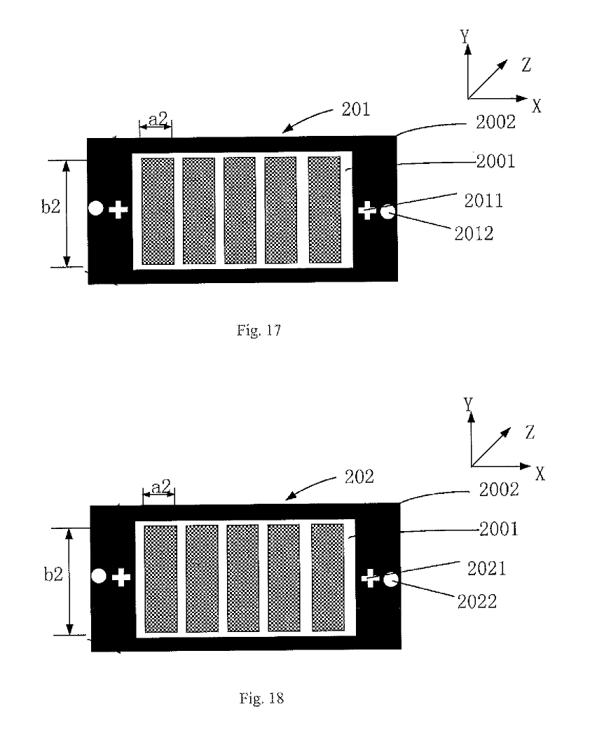

FIG. 17 is a top view of the first mask plate 201 according to this embodiment of the present disclosure, and FIG. 18 is a top view of the second mask plate 202 according to this embodiment of the present disclosure. As shown in FIG. 17, the first mask plate 201 includes the mask plate pattern region 2001, the bezel region 2002, and the second alignment marks 2011 and fifth alignment marks 2012 at the bezel region 2002. As shown in FIG. 18, the second mask plate 202 includes the mask plate pattern region 2001, the bezel region 2002, and the third alignment marks 2021 and sixth alignment marks 2022 at the bezel region 2002. Alternatively, there are two second alignment marks 2011 and two fifth alignment marks 2012 on the first mask plate 201, and two third alignment marks 2021 and two sixth alignment marks 2022 on the second mask plate 202.

In this embodiment, alternatively, the first mask plate 201 and the second mask plate 202 are of an identical structure, a width b2 of each of the mask plate pattern regions 2001 of the first mask plate 201 and the second mask plate 202 in the first direction Y is less than a width b1 of the pattern at the sub-region 1012, and a width a2 of each of the mask plate pattern region 2001 of the first mask plate 201 and the second mask plate 202 in the second direction X is identical to a width a1 of the sub-region 1012 in the second direction X. As a result, a width of the effective mask plate pattern region A in the first direction Y is less than a width of the current sub-region 1012 of the substrate 100, and a width of the effective mask plate pattern region A in the second direction X perpendicular to the first direction Y is identical to a width of the current-region 1012 of the substrate 100 in the second direction X.

Of course, it should be appreciated that, in the actual application, the first mask plate 201 and the second mask plate 202 may also be of different structures, and their mask plate pattern regions 2001 may each be of a size different from the sub-region 1012, as long as the effective mask plate pattern region A formed after the mask plate pattern regions 2001 of the first mask plate 201 and the second mask plate 202 overlap each other is of a size identical to the sub-region 1012.

Before the startup of the evaporation, the first mask plate 201 is aligned with the current sub-region 1012 by the alignment mechanism through the first alignment marks 1011 on the substrate 100 and the second alignment marks 2011 on the first mask plate 201, and the second mask plate 202 is aligned with the current sub-region 1012 by the alignment mechanism through the first alignment marks 1011 on the substrate 100 and the third alignment marks 2021 on the second mask plate 202. To be specific, the substrate 100 and/or the first/second mask plates are moved, so as to enable the corresponding first alignment marks 1011 on the substrate 100 to visually overlap the corresponding second and third alignment marks 2011, 2021 on the first and second mask plates 201, 202, respectively, thereby to complete the alignment.

During the evaporation, the evaporation source 300, the shutter 400, the first mask plate 201 and the second mask plate 202 are located at fixed positions. The vaporized material passes through the effective mask plate pattern region A formed after the first mask plate 201 overlaps the second mask plate 202. The substrate 100 moves in the first direction Y under the effect of the substrate driving mechanism, until one of the sub-regions 1012 is processed by the vacuum evaporation. The first mask plate 201 is initially aligned with the sub-region 1012 to be processed by evaporation by the alignment mechanism through the first alignment marks 1011 on the substrate 100 and the second alignment marks 2011 on the first mask plate 201, and the second mask plate 202 is initially aligned with the sub-region 1012 to be processed by evaporation by the alignment mechanism through the first alignment marks 1011 on the substrate 100 and the third alignment marks 2021 on the second mask plate 202. During the movement of the substrate in the first direction Y, i.e., during the scanning and evaporation procedure, the first and second mask plates are aligned with the current sub-region by the alignment mechanism through the fourth alignment marks 1013 on the substrate, the fifth alignment marks 2012 on the first mask plate 201 and the sixth alignment marks 2022 on the second mask plate 202, in a state where a relative position between the first/second mask plates and the current sub-region is changed continuously in the first direction Y. Then, the first mask plate driving mechanism and the second mask plate driving mechanism fine-tune the positions of the first mask plate 201 and the second mask plate 202 in the second direction X in accordance with the alignment results, respectively, so that the first mask plate 201 and the second mask plate 202 are not offset from the sub-region 1012 to be processed by evaporation in the second direction X. After the first sub-region 1012 is processed by evaporation, the above operations are repeated so as to process the other sub-regions, e.g., the second sub-region 1012, until the entire substrate 100 is processed by the vacuum evaporation.

It should be appreciated that, in this embodiment, the sub-regions 1012 are of an identical area. Of course, in the other embodiments, the sub-regions 1012 may also be of different areas, and at this time, it is required to move the shutter 400 or adjust the relative position relationship among the sub-shutters 401, so as to shield a part of the mask plate pattern region 2001.

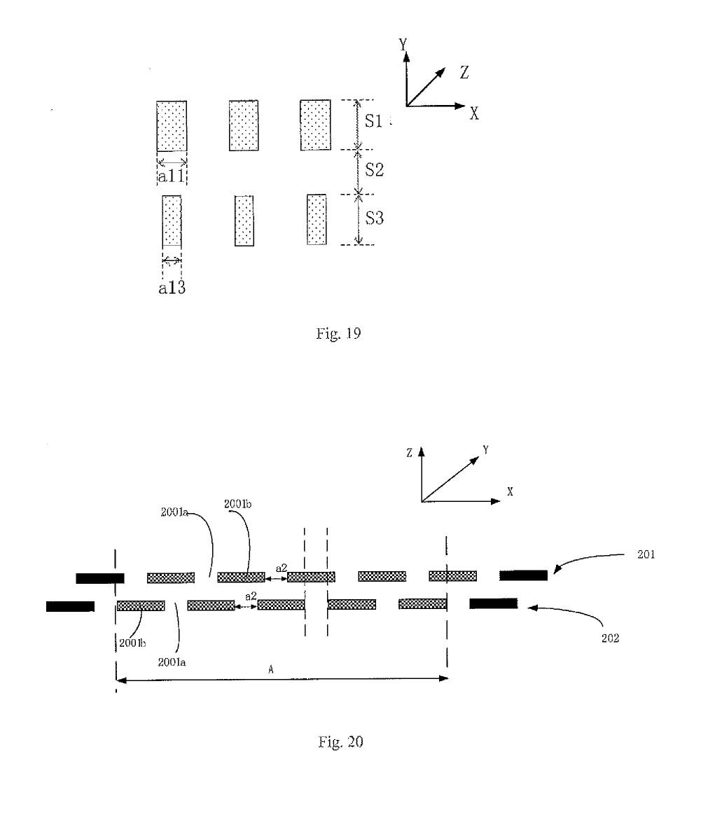

As shown in FIG. 19, which is a schematic view showing the pattern of the sub-region for a block-like pixel, the sub-region 1012 includes a first region S1, a second region S2 and a third region S3 arranged sequentially in the first direction Y. In the second direction X, a width all of the pattern of the film at the first region S1 is identical to the width a2 of each of the aperture portions 2001a of the mask plate pattern regions of the first mask plate 201 and the second mask plate 202. A width of the pattern of the film at the second region S2 is 0, i.e., no film is formed at this region. A width a13 of the pattern of the film at the third region S3 is less than the width a2 of each of the aperture portions 2001a of the mask plate pattern regions 2001 of the first mask plate 201 and the second mask plate 202.

When forming the film in FIG. 19 by evaporation, the operating procedure of the vacuum evaporation device in this embodiment will be described hereinafter.

In a direction where the line evaporation source 300 scans the surface of the substrate 100 (i.e., the first direction Y), when the line evaporation source 300 scans the first region S1, the aperture portions 2001 of the mask plate pattern regions 2001 of the first mask plate 201 and the second mask plate 202 overlap each other exactly. At this time, the relative position relationship between the first mask plate 201 and the second mask plate 202 is shown in FIG. 9. A width of the effective aperture portion of the effective mask plate pattern region A is identical to the width all of the pattern of the film at the first region S1, and no film is formed at the second region S2 by evaporation. When the line evaporation source 300 scans the second region S2, each of the aperture portions 2001a of the mask plate pattern regions 2001 of the first mask plate 201 and the second mask plate 202 is fully shielded by the first mask plate 201 or the second mask plate 202. At this time, the relative position relationship between the first mask plate 201 and the second mask plate 202 is shown in FIG. 20. When the line evaporation source 300 scans the third region S3, each of the aperture portions 2001a of the mask plate pattern regions 2001 of the first mask plate 201 and the second mask plate 202 is partially shielded by the first mask plate 201 or the second mask plate 202, and the width of the effective aperture portion is identical to the width a13 of the pattern of the film at the third region S3 in the second direction X.

According to the vacuum evaporation device in the embodiments of the present disclosure, at least two mask plates are provided, and the overlapping state of the mask plate pattern regions on the at least two mask plates may be changed in accordance with the pattern features of the pattern region to be processed by evaporation at the surface of the substrate, so as to enable the effective mask plate pattern region to match the pattern region to be processed by evaporation at the surface of the substrate, thereby to pattern the film and reduce the production cost of the mask plates. Further, the surface of the substrate 100 is divided into several (e.g., 1 to 10) sub-regions 1012 in accordance with the features of the pattern region to be processed by evaporation at the surface of the substrate 100, and the mask plate having an area several times smaller than the substrate 100 or the sub-region 1012 may be used to perform the evaporation on each sub-region 1012 in a stepwise manner. When the sub-region 1012 with a relatively small area is processed by evaporation, it is able to reduce a length of the line evaporation source 300 and improve the evenness of the vacuum evaporation. When the mask plate having an area several times smaller than the substrate 100 or the sub-region 1012 is used, it is able to reduce the difficulty in manufacturing the mask plate, thereby to perform the vacuum evaporation on the large-sized substrate 100 and the large-sized display module.

The above embodiments are for illustrative purposes merely, but shall not be used to limit the present disclosure. It should be appreciated that, a person skilled in the art may make further modifications or substitutions without departing from the spirit of the present disclosure, and these modifications or substitutions shall also fall within the scope of the present disclosure.

1. A vacuum evaporation device, comprising:
a substrate driving mechanism for supporting and moving a substrate;
a first mask plate driving mechanism for supporting and moving a first mask plate located below the substrate;
a second mask plate driving mechanism for supporting and moving a second mask plate located below the first mask plate; and
an evaporation source located below the second mask plate.

2. The vacuum evaporation device according to claim 1, wherein the first mask plate driving mechanism and the second mask plate driving mechanism move the first mask plate and second mask plate, respectively, so as to change an overlapping state of mask plate pattern regions of the first mask plate and the second mask plate, thereby to form an effective mask plate pattern region corresponding to a pattern region to be processed by evaporation on the substrate.

3. The vacuum evaporation device according to claim 1, wherein
a surface of the substrate is divided into several sub-regions, and
the effective mask plate pattern region formed after the first mask plate overlaps the second mask plate is of a size smaller than, or identical to, that of the sub-region.

4. The vacuum evaporation device according to claim 3, further comprising:
a shutter located between the substrate and the evaporation source so as to form an vaporized-material passing-through region which is of a size identical to that of the effective mask plate pattern region;
a shutter driving mechanism for moving and supporting the shutter, so as to enable the vaporized-material passing-through region to correspond to a current sub-region of the substrate; and
an evaporation source driving mechanism for moving and supporting the evaporation source, so as to enable the evaporation source to correspond to the current sub-region of the substrate.

5. The vacuum evaporation device according to claim 4, further comprising:
an alignment mechanism for aligning the first mask plate and the second mask plate with the current sub-region of the substrate, respectively.

6. The vacuum evaporation device according to claim 5, further comprising an alignment driving mechanism for moving and supporting the alignment mechanism.

7. The vacuum evaporation device according to claim 5, wherein when the effective mask plate pattern region formed after the first mask plate overlaps the second mask plate is of a size identical to that of the sub-region, a first alignment mark is provided outside the sub-region, a second alignment mark is provided at a bezel region of the first mask plate, a third alignment mark is provided at a bezel region of the second mask plate, the first mask plate is aligned with the current sub-region by the alignment mechanism through the first alignment mark and the second alignment mark, and the second mask plate is aligned with the current sub-region by the alignment mechanism through the first alignment mark and the third alignment mark.

8. The vacuum evaporation device according to claim 6, wherein when the effective mask plate pattern region formed after the first mask plate overlaps the second mask plate is of a size smaller than that of the sub-region,
a first alignment mark is provided outside the sub-region, a second alignment mark is provided at a bezel region of the first mask plate, a third alignment mark is provided at a bezel region of the second mask plate, the first mask plate is aligned with a current sub-region by the alignment mechanism before the startup of the evaporation through the first alignment mark and the second alignment mark, and the second mask plate is aligned with the current sub-region by the alignment mechanism before the startup of the evaporation through the first alignment mark and the third alignment mark; and
a fourth alignment mark is further provided outside the sub-region, a fifth alignment mark is further provided at the bezel region of the first mask plate, a sixth alignment mark is further provided at the bezel region of the second mask plate, the first mask plate is aligned with the current sub-region by the alignment mechanism during the evaporation through the fourth alignment mark and the fifth alignment mark in a state where a relative position between the first mask plate and the current sub-region is changed continuously in the first direction, and the second mask plate is aligned with the current sub-region by the alignment mechanism during the evaporation through the fourth alignment mark and the sixth alignment mark in a state where a relative position between the second mask plate and the current sub-region is changed continuously in the first direction.

9. The vacuum evaporation device according to claim 8, wherein the fourth alignment mark is an elongated structure extending in the first direction and through a corresponding sub-region.

10. The vacuum evaporation device according to claim 8, wherein
the first mask plate driving mechanism adjusts finely a position of the first mask plate in a second direction in accordance with an alignment result in the state where the relative position between the first mask plate and the current sub-region is changed continuously in the first direction, so that the first mask plate is not offset from the current sub-region; and
the second mask plate driving mechanism adjusts finely a position of the second mask plate in the second direction in accordance with an alignment result in the state where the relative position between the second mask plate and the current sub-region is changed continuously in the first direction, so that the second mask plate is not offset from the current sub-region.

11. The vacuum evaporation device according to claim 4, wherein the shutter is located below the second mask plate.

12. The vacuum evaporation device according to claim 4, wherein the shutter comprises four sub-shutters which are driven independently and define the vaporized-material passing-through region.

13. The vacuum evaporation device according to claim 1, wherein the evaporation source is a line evaporation source.

14. A vacuum evaporation method, comprising:
moving, by a substrate driving mechanism, a sub-region on the substrate to be above a first mask plate;
aligning, by an alignment mechanism, a first alignment mark on the substrate with a second alignment mark on the first mask plate and a third alignment mark on a second mask plate through adjusting positions of the first mask plate and the second mask plate by a first mask plate driving mechanism and a second mask plate driving mechanism, respectively; and
turning on an evaporation source, so that a material is vaporized and moves upward until it reaches a surface of the substrate and the vaporized material is deposited on the substrate to form a film with a pattern identical to an effective aperture pattern at an effective mask plate pattern region formed after the first mask plate overlaps the second mask plate.

15. The vacuum evaporation method according to claim 14, wherein when the effective mask plate pattern region formed after the first mask plate overlaps the second mask plate is of a size identical to that of the sub-region, a first alignment mark is provided outside the sub-region, a second alignment mark is provided at a bezel region of the first mask plate, a third alignment mark is provided at a bezel region of the second mask plate, the first mask plate is aligned with a current sub-region by the alignment mechanism through the first alignment mark and the second alignment mark, and the second mask plate is aligned with the current sub-region by the alignment mechanism through the first alignment mark and the third alignment mark.

16. The vacuum evaporation method according to claim 14, wherein when the effective mask plate pattern region formed after the first mask plate overlaps the second mask plate is of a size smaller than that of the sub-region,
a first alignment mark is provided outside the sub-region, a second alignment mark is provided at a bezel region of the first mask plate, a third alignment mark is provided at a bezel region of the second mask plate, the first mask plate is aligned with a current sub-region by the alignment mechanism before the startup of the evaporation through the first alignment mark and the second alignment mark, and the second mask plate is aligned with the current sub-region by the alignment mechanism before the startup of the evaporation through the first alignment mark and the third alignment mark; and
a fourth alignment mark is further provided outside the sub-region, a fifth alignment mark is further provided at the bezel region of the first mask plate, a sixth alignment mark is further provided at the bezel region of the second mask plate, the first mask plate is aligned with the current sub-region by the alignment mechanism during the evaporation through the fourth alignment mark and the fifth alignment mark in a state where a relative position between the first mask plate and the current sub-region is changed continuously in the first direction, and the second mask plate is aligned with the current sub-region by the alignment mechanism during the evaporation through the fourth alignment mark and the sixth alignment mark in a state where a relative position between the second mask plate and the current sub-region is changed continuously in the first direction.

17. The vacuum evaporation method according to claim 16, wherein the fourth alignment mark is an elongated structure extending in the first direction and through a corresponding sub-region.

18. The vacuum evaporation method according to claim 16, wherein
the first mask plate driving mechanism adjusts finely the first mask plate in a second direction in accordance with an alignment result in the state where the relative position between the first mask plate and the current sub-region is changed continuously in the first direction, so that the first mask plate is not offset from the current sub-region, and
the second mask plate driving mechanism adjusts finely the second mask plate in the second direction in accordance with an alignment result in the state where the relative position between the second mask plate and the current sub-region is changed continuously in the first direction, so that the second mask plate is not offset from the current sub-region.

19. The vacuum evaporation method according to claim 17, wherein
the first mask plate driving mechanism adjusts finely the first mask plate in a second direction in accordance with an alignment result in the state where the relative position between the first mask plate and the current sub-region is changed continuously in the first direction, so that the first mask plate is not offset from the current sub-region, and
the second mask plate driving mechanism adjusts finely the second mask plate in the second direction in accordance with an alignment result in the state where the relative position between the second mask plate and the current sub-region is changed continuously in the first direction, so that the second mask plate is not offset from the current sub-region.
